(19) United States
(12) Patent Application Publication
(10) Pub. No.: US 2015/0287863 A1
(43) Pub. Date: Oct. 8, 2015

(54) TRANSPARENT SOLAR CELL

(71) Applicant: ELECTRONICS AND TELECOMMUNICATIONS RESEARCH INSTITUTE, Daejeon (KR)

(72) Inventors: JungWook LIM, Daejeon (KR); Dongwoo SUH, Daejeon (KR); Sun Jin YUN, Daejeon (KR)

(73) Assignee: ELECTRONICS AND TELECOMMUNICATIONS RESEARCH INSTITUTE, Daejeon (KR)

(21) Appl. No.: 14/677,916

(22) Filed: Apr. 2, 2015

(30) Foreign Application Priority Data
Apr. 4, 2014 (KR) 10-2014-0040571
Feb. 5, 2015 (KR) 10-2015-0018042

(51) Int. Cl. H01L 31/054

(52) U.S. Cl. CPC H01L 31/054

(57) ABSTRACT

Provided is a transparent solar cell including: a substrate; a first transparent electrode disposed on the substrate; a light absorption layer disposed on the first transparent electrode; a multi chromic layer disposed on the light absorption layer; and a second transparent electrode disposed on the multi chromic layer, and in which light is incident into the substrate and at least some of the incident light is converted into an electrical current in the light absorption layer to be able to provide heat to the multi chromic layer.

### CROSS-REFERENCE TO RELATED APPLICATIONS

This U.S. non-provisional patent application claims priority under 35 U.S.C. §119 of Korean Patent Application Nos. 10-2014-0040571, filed on Apr. 4, 2014, and 10-2015-0018042, filed on Feb. 5, 2015, the entire contents of which are hereby incorporated by reference.

### BACKGROUND

The present disclosure herein relates to a transparent solar cell, and more particularly, to a transparent solar cell controlling an infrared ray.

Building integrated photovoltaics (BIPV) currently applied to houses or buildings is a very suitable form of a solar cell to the country where land area is small and many buildings exist. In particular, when a transparent solar cell is applied to a glass window, a substantial amount of power generation is expected in a building with a high proportion of front window. In addition, when accompanied by a color realization technology of the transparent solar cell, it is also aesthetically very advantageous.

When an infrared ray is transmitted through a glass window of a building or a car, an indoor temperature is highly increased by the greenhouse effect. There has been an effort to block an infrared ray with a solar cell to prevent an increase in indoor temperature.

### SUMMARY

The present disclosure provides a transparent solar cell having a function of controlling or blocking the amount of an infrared ray.

The object of the present invention is not limited to the aforesaid, but other objects not described herein will be clearly understood by those skilled in the art from descriptions below.

Embodiments of the present invention provide transparent solar cells including: a substrate; a first transparent electrode disposed on the substrate; a light absorption layer disposed on the first transparent electrode; a multi chromic layer disposed on the light absorption layer; and a second transparent electrode disposed on the multi chromic layer, and in which light is incident into the substrate and at least some of the incident light is converted into an electrical current in the light absorption layer to be able to provide heat to the multi chromic layer.

In some embodiments, the transparent solar cell may further include an intermediate layer between the light absorption layer and the multi chromic layer.

In other embodiments, the intermediate layer may be an optical thin film having a color.

In still other embodiments, the transparent solar cell may further include a resistance layer between the light absorption layer and the multi chromic layer.

In even other embodiments, the resistance layer may include a high resistance material.

In yet other embodiments, the resistance layer may include any one material selected from the group consisting of ITO, ZnO, ZnO:Ga, ZnO:Al, SnO₂, TiO₂, Al₂O₃, ZrO₂, SiO₂, and carbon nanotube (CNT).

In further embodiments, the resistance layer may generate Joule's heat and the Joule's heat may raise a temperature of the multi chromic layer.

In still further embodiments, the transparent solar cell may further include: a third transparent electrode disposed on a first region between the light absorption layer and the resistance layer; a first insulating layer disposed on a second region between the light absorption layer and the resistance layer except for the first region; and a second insulating layer disposed between the resistance layer and the second transparent electrode.

In even further embodiments, the transparent solar cell may further include a wire being adjacent to the second region and connecting the first transparent electrode with the second transparent electrode.

In yet further embodiments, the first transparent electrode may include one side surface and another side surface, and the second transparent electrode may include one side surface in contact with the one side surface of the first transparent electrode and another side surface in contact with the another side surface of the first transparent electrode and may further include a wire in contact with the another side surface of the first transparent electrode and the another side surface of the second transparent electrode, and the one side surface of the first transparent electrode is in contact with one side surface of the third transparent electrode and the another side surface of the first transparent electrode may be spaced apart from another side surface facing the one side surface of the third transparent electrode.

In much further embodiments, the first insulating layer may increase a travel distance of an electrical current which moves from the light absorption layer to the resistance layer and is generated in the light absorption layer to be able to increase an electrical resistance.

In still much further embodiments, the second insulating layer may increase a travel distance of an electrical current which moves from the resistance layer to the multi chromic layer and is generated in the light absorption layer to be able to increase an electrical resistance.

In even much further embodiments, the first and second insulating layers may include silicon oxide or silicon nitride.

In yet much further embodiments, the multi chromic layer may include a material in which phase transition occurs according to a temperature.

In some embodiments, the multi chromic layer may include vanadium oxide (VOₓ) (1<x<3).

In other embodiments, a transition temperature of the multi chromic layer may change due to any one of element doping, light, and voltage.

In still other embodiments, the element may include tungsten, chromium, or lanthanide element.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a transparent solar cell according to an embodiment of the present invention;

FIG. 2 is a graph illustrating a transmission amount of infrared rays in a multi chromic layer according to a temperature according to an embodiment of the present invention;

FIG. 3 is a cross-sectional view illustrating a transparent solar cell according to another embodiment of the present invention;

FIG. 4 is a graph illustrating an electrical current-voltage characteristic of a transparent solar cell according to a solar altitude according to an embodiment of the present invention;

FIG. 5 is a graph illustrating infrared transmission in an infrared ray control layer of a transparent solar cell according to a solar altitude according to an embodiment of the present invention; and

FIG. 6 is a picture illustrating that a transparent solar cell applied to a sunroof of a car blocks an infrared ray according to an embodiment of the present invention.

### DETAILED DESCRIPTION OF THE EMBODIMENTS

Advantages and features of the present the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present the present invention to those skilled in the art. Further, the present the present invention is only defined by scopes of claims. Like reference numerals refer to like elements throughout.

In the following description, the technical terms are used only for explaining a specific exemplary embodiment while not limiting the present the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, the embodiment in the detailed description will be described with reference to sectional views and/or plan views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a device region. Thus, this should not be construed as limited to the scope of the present invention.

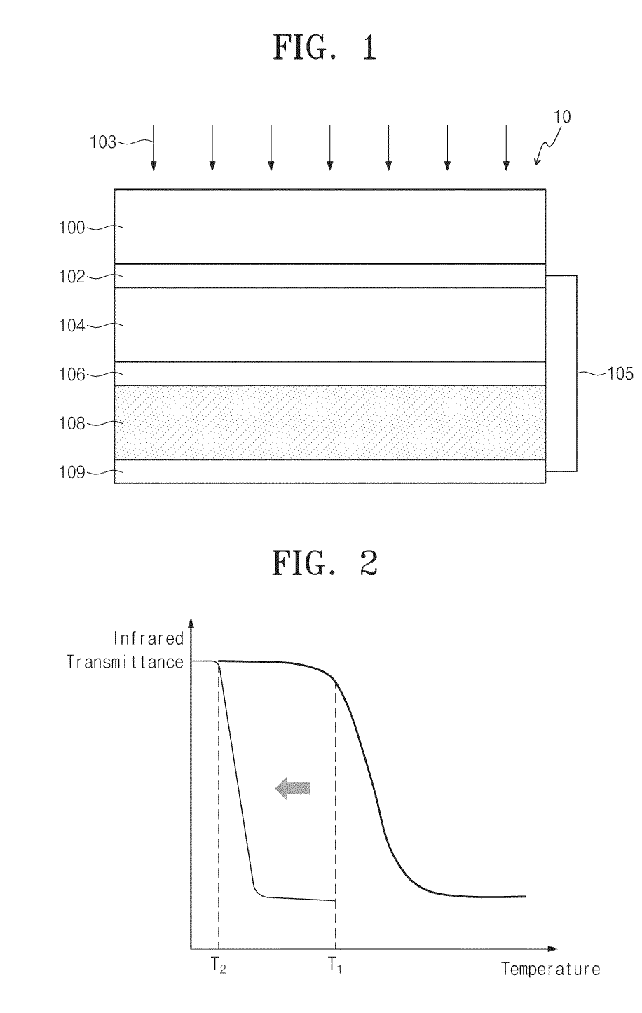

FIG. 1 is a cross-sectional view illustrating a transparent solar cell according to an embodiment of the present the present invention. FIG. 2 is a graph illustrating a transmission amount of infrared rays in a multi chromic layer according to a temperature according to an embodiment of the present invention.

Referring to FIG. 1, a transparent solar cell 10 includes a substrate 100, and a first transparent electrode 102, a light absorption layer 104, an intermediate layer 106, a multi chromic layer 108, and a second transparent electrode 109 which are sequentially stacked on the substrate 10. A wire is connected between the first transparent electrode 102 and the second transparent electrode 109 so that a voltage may be applied therebetween.

The substrate 100 may be a transparent glass substrate or a transparent plastic substrate. The transparent plastic substrate may be formed of, for example, polyether sulfone (PES), polyethylenenaphthalate (PEN), polyethylene terephalate (PET), polycarbonate (PC), polystyrene (PS), polypropylene, polyamide, poly methyl methacrylate (PMMA), polyesterimide, polymethylpentene (PMP), polyimide, or an acrylic material.

The first transparent electrode 102 may be formed of a conductive material. The first transparent electrode 102 may be formed of any one material of, for example, ITO, ZnO:Al, ZnO:Ga, SnO₂:F, F-doped SnO₂ (FTO), ZnO, antimony Tin Oxide (ATO), WOx, MoOx, and ZnO/Ag/ZnO.

The light absorption layer 104 may be any one of an amorphous silicon layer, a microcrystalline silicon layer, a semiconductor layer of a Group I-III-VI₂ compound, a dye-sensitized semiconductor layer in which the dye particles and a metal oxide are mixed, an organic semiconductor layer, and a silicon quantum dot semiconductor layer.

The intermediate layer 106 may be an optical thin film having a color. The intermediate layer 106 may include a transparent electrode material or an oxide. The intermediate layer 106 may include, for example, ITO, alumina (Al₂O₃), silicon dioxide (SiO₂), titanium dioxide (TiO₂), or zinc oxide (ZnO). The intermediate layer 106 may have a thickness ranging from about 10 nm to about 1000 nm.

The multi chromic layer 108 may include a material in which phase transition occurs according to a temperature. The multi chromic layer 108 may be formed of vanadium oxide (VOₓ) (1<x<3). A phase transition temperature of the vanadium oxide is about 68° C. Therefore, when the multi chromic layer 108 reaches the temperature of about 68° C., the vanadium oxide is metalized through a phase transition, so that infrared rays in a long wavelength region may be blocked. The phase transition temperature of the multi chromic layer 108 may change due to any one factor of element doping, light, and voltage. For example, a transition element (for example, tungsten (W), chromium (Cr)) or a lanthanide element may be doped into the multi chromic layer 108 so that the transition temperature of the multi chromic layer 108 may be lowered. In another example, when light is introduced into the multi chromic layer 108 or a voltage is applied to the multi chromic layer 108, the transition temperature of the multi chromic layer 108 may be lowered.

Referring to FIG. 2, when at least any one of the above factors is satisfied, the transition temperature of the multi chromic layer 108 moves from a first transition temperature T1 to a second transition temperature T2. Therefore, a phase transition occurs in the multi chromic layer 108 at the second transition temperature T2 so that infrared rays may be blocked. The multi chromic layer 108 may be controlled to block the infrared rays by using the factors at a desired temperature.

Referring back to FIG. 1, the second transparent electrode 109 may be formed of a transparent conductive material. The second transparent electrode 109 may include a same or a different material as the first transparent electrode 102. The second transparent electrode 109 may be formed of any one material of, for example, ITO, ZnO:Al, ZnO:Ga, SnO₂:F, F-doped SnO₂ (FTO), ZnO, antimony Tin Oxide (ATO), WOx, MoOx, and ZnO/Ag/ZnO.

When light 103 is introduced into the substrate 100, the light 103 is absorbed by the light absorption layer 104 through the substrate 100 and the first transparent electrode 102. The light 103 is converted to an electron-hole pair so that an electrical current is generated in the light absorption layer 104. All the light 103 introduced into the substrate 100 is not absorbed in the light absorption layer 104 and some of the light 103 transmits the intermediate layer 106, the multi chromic layer 108, and the second transparent electrode 109, so that a transparent solar cell may be realized. Heat generated by the electrical current raises the temperature of the multi chromic layer 108 and the multi chromic layer 108 in which the temperature thereof is increased more than the transition temperature blocks infrared rays. Therefore, while having the function of the solar cell, the transparent solar cell may suppress a temperature rise caused by the indoor greenhouse effect by blocking infrared rays.

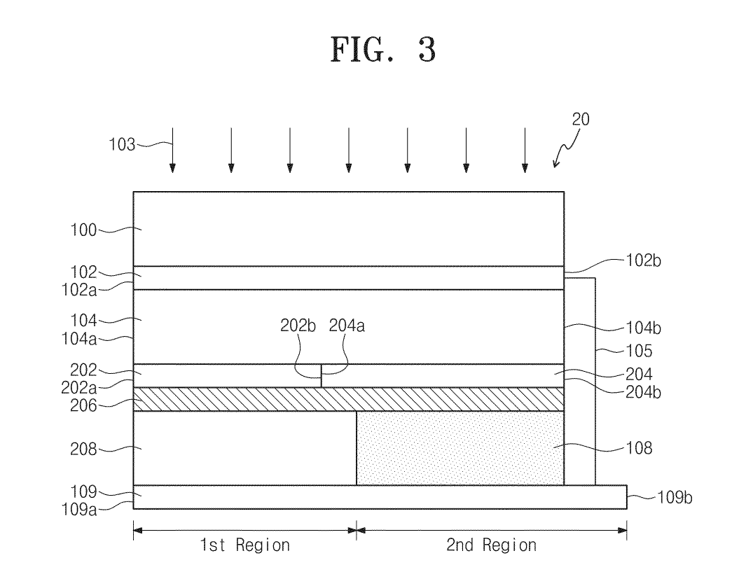

FIG. 3 is a cross-sectional view illustrating a transparent solar cell according to another embodiment of the present invention. For simplicity of explanation, in another embodiment in FIG. 3, the same reference numerals are used for substantially the same elements as those of the one embodiment and a description thereof will be omitted.

Referring to FIG. 3, a transparent solar cell 20 includes a substrate 100, and a first transparent electrode 102, a light absorption layer 104, and a second transparent electrode 109 which are sequentially stacked on one surface of the substrate 100. A wire 105 is connected between the first transparent electrode 102 and the second transparent electrode 109 so that a voltage may be applied therebetween. Specifically, the first transparent electrode 102 may include one side surface 102a and another side surface 102b, and the second transparent electrode 109 may include one side surface 109a and another side surface 109b. The wire 105 may be in contact with the another side surface 102b of the first transparent electrode 102 and the another side surface 109b of the second transparent electrode 109. A third transparent electrode 202, a first insulating layer 204, a resistance layer 206, a second insulating layer 208, and a multi chromic layer 108 may be disposed between the light absorption layer 104 and the second transparent electrode 109.

Specifically, the third transparent electrode 202 is disposed in a first region of the light absorption layer 104 and the first insulating layer 204 is disposed in a second region of the light absorbing layer 104. The wire 105 may be disposed adjacent to the second region. More specifically, the light absorption layer 104 may include one side surface 104a and another side surface 104b. The third transparent electrode 202 may include one side surface 202a and another side surface 202b. The first insulating layer 204 may include one side surface 204a and another side surface 204b. The one side surface 104a of the light absorption layer 104 may contact the one side surface 102a of the first transparent electrode 102 and the one side surface 202a of the third transparent electrode 202. The another side surface 104b of the light absorption layer 104 may contact the another side surface 102b of the first transparent electrode 102 and the another side surface 204b of the first insulating layer 204. The another side surface 202b of the third transparent electrode 202 may contact the one side surface 204a of the first insulating layer 204 and may be spaced apart from the another side surface 102b of the first transparent electrode 102 and the another side surface 109b of the second transparent electrode 109. The resistance layer 206 may be disposed to cover the third transparent electrode 202 and the first insulating layer 204.

An electrical current generated in the light absorption layer 104 moves to the resistance layer 206 through the third transparent electrode 202. The first insulating layer 204 may have a function of increasing a resistance. Specifically, the first insulating layer 204 is disposed in a partial region between the light absorption layer 104 and the resistance layer 206, and the partial region may be more adjacent to the wire 105. Therefore, it is possible to increase the travel distance of the electrical current to increase the resistance.

The third transparent electrode 202 may be formed of a transparent conductive material. The third transparent electrode 202 may be formed of any one material of, for example, ITO, ZnO:Al, ZnO:Ga, SnO₂:F, F-doped SnO₂ (FTO), ZnO, Antimony Tin Oxide (ATO), WOₓ, MoOₓ, and ZnO/Ag/ZnO. The first insulating layer 204 may be formed of silicon oxide or silicon nitride.

The resistance layer 206 may include a high resistance material. The resistance layer 206 may be transparent. The resistance layer 206 may generate Joule's heat (I2R). Heat generated in the light absorbing layer 104 is limited. The resistance layer 206 may allow the multi chromic layer 108 to reach a transition temperature quickly by generating more heat than heat generated in the light absorption layer 104 to apply heat to the multi chromic layer 108 disposed adjacent to the resistance layer 206. The resistance layer 206 may be formed of any one material selected from the group consisting of ITO, ZnO, ZnO:Ga, ZnO:Al, SnO₂, TiO₂, Al₂O₃, ZrO₂, SiO₂, and carbon nanotube (CNT), for example.

The second insulating layer 208 is disposed in the first region of one surface of the resistance layer 206, and the multi chromic layer 108 may be disposed on the second region of one surface of the resistance layer 206. The second insulating layer 208 and the multi chromic layer 108 cover the one surface of the resistance layer 206, and may be in contact with the second transparent electrode 109. The second insulating layer 208 may increase the travel distance of an electrical current from the resistance layer 206 to the multi chromic layer 208 to increase the electrical resistance. The second insulating layer 208 may be formed of silicon oxide or silicon nitride.

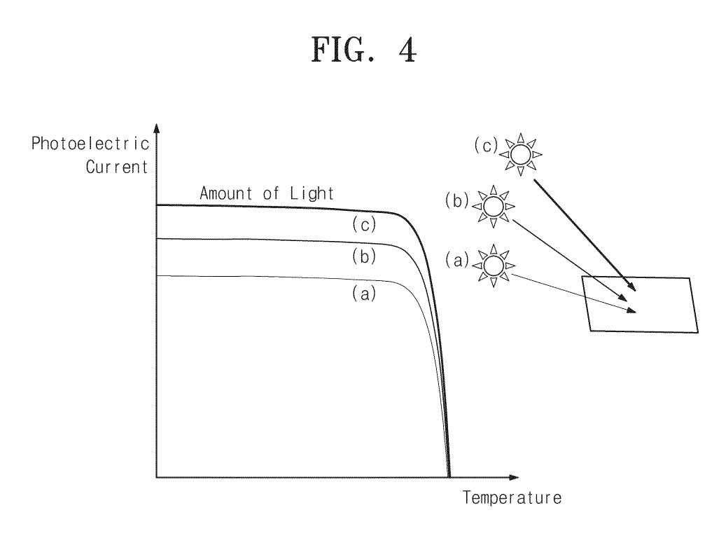

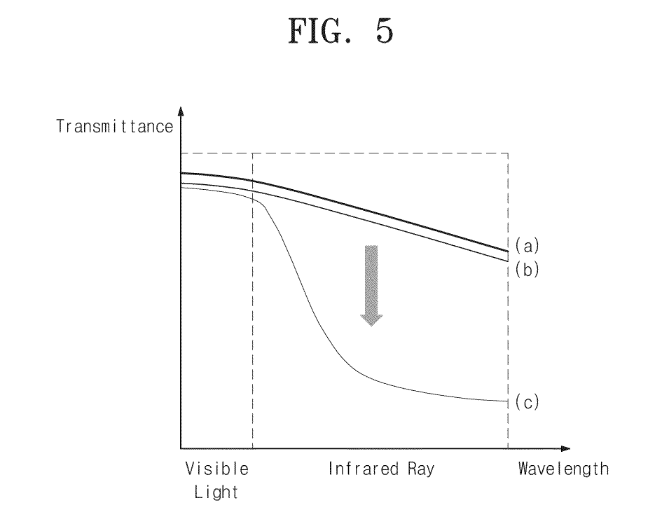

FIG. 4 is a graph illustrating an electrical current-voltage characteristic of a transparent solar cell according to a solar altitude according to an embodiment of the present invention. FIG. 5 is a graph illustrating infrared transmission in an infrared ray control layer of a transparent solar cell according to a solar altitude according to an embodiment of the present invention.

Referring to FIGS. 4 and 5, the higher the sun altitude is from (a) to (c), the more the amount of incident light. As the amount of light is increased, the electrical current generated in the transparent solar cell is increased too. Heat is generated in the light absorption layer of the transparent solar cell by the electrical current, and the temperature of the multi chromic layer is increased by the heat. Accordingly, time necessary for the electrical current to be generated in the light absorption layer when sun altitude is (c) is less than when sun altitude is (a) and/or (b), so that the transparent solar cell may block infrared rays quickly when the sun altitude is (c).

The sun's altitude of meridian passage is higher in summer than in winter. The transparent solar cell of the present invention blocks infrared rays to be able to lower an indoor temperature in summer when sun's altitude is high, and passes infrared rays or blocks small amount of infrared rays to be able to keep an indoor temperature warm in winter when suds altitude is low.

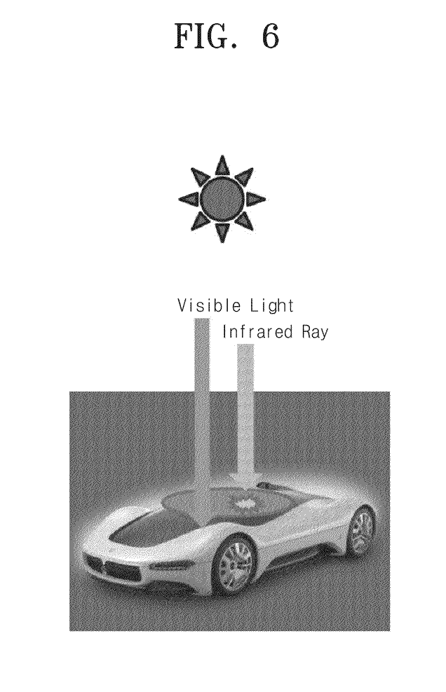

FIG. 6 is a picture illustrating that a transparent solar cell applied to a sunroof of a car is cutting infrared rays according to an embodiment of the present invention.

Referring to FIG. 6, an indoor temperature of a car may be prevented from being raised by light by applying a transparent solar cell according to the present invention to a sunroof of a car. Therefore, by reducing the use of an air conditioner to lower an indoor temperature of the car in summer, it is possible to reduce the use of fuel.

The transparent solar cell according to embodiments of the present invention may block infrared rays increasing an indoor temperature or control the amount of infrared rays. Therefore, it is possible to suppress temperature rise caused by the indoor greenhouse effect.

The above-disclosed subject matter is to be considered illustrative and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A transparent solar cell, comprising:
a substrate;
a first transparent electrode disposed on the substrate;
a light absorption layer disposed on the first transparent electrode;
a multi chromic layer disposed on the light absorption layer; and
a second transparent electrode disposed on the multi chromic layer,
wherein at least some of incident light is converted into an electrical current in the light absorption layer to provide heat to the multi chromic layer.

2. The transparent solar cell of claim 1, further comprising an intermediate layer between the light absorption layer and the multi chromic layer.

3. The transparent solar cell of claim 2, wherein the intermediate layer is an optical thin film having a color.

4. The transparent solar cell of claim 1, further comprising a resistance layer between the light absorption layer and the multi chromic layer.

5. The transparent solar cell of claim 4, wherein the resistance layer comprises a high resistance material.

6. The transparent solar cell of claim 5, wherein the resistance layer comprises any one material selected from the group consisting of ITO, ZnO, ZnO:Ga, ZnO:Al, SnO₂, TiO₂, Al₂O₃, ZrO₂, SiO₂, and carbon nanotube (CNT).

7. The transparent solar cell of claim 4, wherein the resistance layer generates Joule's heat and the Joule's heat raises a temperature of the multi chromic layer.

8. The transparent solar cell of claim 4, further comprising:
a third transparent electrode disposed on a first region between the light absorption layer and the resistance layer;
a first insulating layer disposed on a second region between the light absorption layer and the resistance layer except for the first region; and
a second insulating layer disposed between the resistance layer and the second transparent electrode.

9. The transparent solar cell of claim 8, further comprising a wire being adjacent to the second region and connecting the first transparent electrode with the second transparent electrode.

10. The transparent solar cell of claim 8, wherein the first transparent electrode comprises one side surface and another side surface, and the second transparent electrode comprises one side surface in contact with the one side surface of the first transparent electrode and another side surface in contact with the another side surface of the first transparent electrode and further comprises a wire in contact with the other side surface of the first transparent electrode and the other side surface of the second transparent electrode, and the one side surface of the first transparent electrode is in contact with one side surface of the third transparent electrode and the other side surface of the first transparent electrode is spaced apart from another side surface facing the one side surface of the third transparent electrode.

11. The transparent solar cell of claim 8, wherein the first insulating layer increases a travel distance of an electrical current which moves from the light absorption layer to the resistance layer and is generated in the light absorption layer to increase an electrical resistance.

12. The transparent solar cell of claim 8, wherein the second insulating layer increases a travel distance of an electrical current which moves from the resistance layer to the multi chromic layer and is generated in the light absorption layer to increase an electrical resistance.

13. The transparent solar cell of claim 8, wherein the first and second insulating layers comprise silicon oxide or silicon nitride.

14. The transparent solar cell of claim 1, wherein the multi chromic layer comprises a material in which phase transition occurs according to a temperature.

15. The transparent solar cell of claim 14, wherein the multi chromic layer comprises vanadium oxide (VOₓ) (1<x<3).

16. The transparent solar cell of claim 1, wherein a transition temperature of the multi chromic layer changes due to any one of element doping, light, and voltage.

17. The transparent solar cell of claim 16, wherein the element comprises tungsten, chromium, or lanthanide element.
